(19) United States
(12) Patent Application Publication
(10) Pub. No.: US 2010/0123140 A1
(43) Pub. Date: May 20, 2010

(54) SiC SUBSTRATES, SEMICONDUCTOR DEVICES BASED UPON THE SAME AND METHODS FOR THEIR MANUFACTURE

(75) Inventors: Victor Lienkong Lou, Schenectady, NY (US); Kevin Sean Matocha, Rexford, NY (US); Aveek Chatterjee, Bangalore (IN); Vinayak Tilak, Niskayuna, NY (US); Stephen Arthur, Glenville, NY (US); Zachary Stum, Niskayuna, NY (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 12/275,067

(22) Filed: Nov. 20, 2008

(51) Int. Cl. H01L 21/30; H01L 29/24

(52) U.S. Cl. 257/77; 438/510; 257/E29.104; 257/E21.211

(57) ABSTRACT

The present invention generally relates to a method for improving inversion layer mobility and providing low defect density in a semiconductor device based upon a silicon carbide (SiC) substrate. More specifically, the present invention provides a method for the manufacture of a semiconductor device based upon a silicon carbide substrate and comprising an oxide layer comprising incorporating at least one additive into the atomic structure of the oxide layer. Semiconductor devices, such as MOSFETS, based upon a substrate treated according to the present method are expected to have inversion layer mobilities of at least about 60 cm²/Vs.

### BACKGROUND

Silicon (Si) is the most widely used semiconductor material, and has been for many years. Due to intense commercial interest and resulting research and development, silicon device technology has reached an advanced level, and in fact, many believe that silicon power devices are approaching the theoretical maximum power limit predicted for this material. Further refinements in this material are not likely to yield substantial improvements in performance, and as a result, development efforts have shifted in focus to the development of other wide bandgap semiconductors as replacements for silicon.

Silicon carbide (SiC) has many desirable properties for high voltage, high frequency and high temperature applications. More particularly, SiC has a large critical electric field (10 times higher than that of Si), a large bandgap (3 times that of Si), a large thermal conductivity (4 times that of Si) and a large electron saturation velocity (twice that of Si). These properties support the theory that SiC will excel over conventional power device applications, such as MOSFETs, SiC n-channel enhancement mode MOSFETs, and SiC diodes such as a merged PIN Schottky (MPS) or a junction barrier Schottky diode (JBS).

Generally, in order to use silicon carbide substrates as the basis for semiconductor devices, an oxide layer must be formed on the SiC substrate. Although theoretically, the oxide can be formed on either the C-face or the Si-face of the SiC crystal, epitaxial layers grown on the C-face are not commercially available and so, MOSFET devices on 0001-Si face 4H-SiC are most sought after.

The performance of these devices is predominantly affected by the on-resistance of the channel, for power devices around and below 2 KV. The channel on-resistance, in turn, is largely controlled by the electron mobility in the inversion layer. Unfortunately, SiC MOSFETs fabricated on the Si-face of a SiC substrate have shown poor inversion layer mobility, which can result in large power dissipation and loss of efficiency.

The mobility, and furthermore the stability of the gate attributes over the expected life of the device, are largely controlled by the poor interface between the gate oxide and the silicon carbide substrate through which the current conduction occurs. Specifically, the interface between the gate oxide and the SiC substrate may typically have a large number of interface traps, or defects, which in various ways interact with electrons moving through the inversion channel.

It would thus be desirable to provide such devices with improved inversion layer mobility, as well as a lower density of defects at the gate oxide/SiC interface.

### BRIEF DESCRIPTION

In a first aspect, there is provided a silicon carbide substrate comprising a gate oxide layer for use in the manufacture of a semiconductor device having at least one additive incorporated into the atomic structure of the oxide layer.

In a second aspect, a method for the manufacture of a semiconductor device based upon a silicon carbide substrate and comprising an oxide layer is provided. The method comprises incorporating at least one additive into the atomic structure of the oxide layer so that at least some portion of the additive is available to reactions occurring at the interface of the silicon carbide substrate and the oxide layer.

### DRAWINGS

These and other features, aspects, and advantages of the present invention will become better understood when the following detailed description is read with reference to the accompanying drawings in which like characters represent like parts throughout the drawings, wherein:

FIG. 1 is a flow-chart schematically illustrating one embodiment of the present method;

FIG. 2 is a flow-chart schematically illustrating an additional embodiment of the present method;

FIG. 3 is a flow-chart schematically illustrating a further embodiment of the present method;

FIG. 4 is a flow-chart schematically illustrating yet another embodiment of the present method;

FIG. 5 is a cross sectional view of an in-process semiconductor device;

FIG. 6 is a cross sectional view of the device of FIG. 5, once subjected to an oxidation process according to one embodiment of the present method;

FIG. 7 is a cross sectional view of a completed SiC MOSFET based upon the device shown in FIGS. 5 and 6;

FIG. 8 is a cross sectional device of an additional semiconductor device advantageously processed according to embodiments of the present invention; and

FIG. 9 is a graphical depiction of field-effect mobilities with increasing gate voltages of devices according to one embodiment of the invention.

### DETAILED DESCRIPTION

Unless defined otherwise, technical and scientific terms used herein have the same meaning as is commonly understood by one of skill in the art to which this invention belongs. The terms “first”, “second”, and the like, as used herein do not denote any order, quantity, or importance, but rather are used to distinguish one element from another. Also, the terms “a” and “an” do not denote a limitation of quantity, but rather denote the presence of at least one of the referenced item, and the terms “front”, “back”, “bottom”, and/or “top”, unless otherwise noted, are merely used for convenience of description, and are not limited to any one position or spatial orientation. If ranges are disclosed, the endpoints of all ranges directed to the same component or property are inclusive and independently combinable (e.g., ranges of “up to about 25 wt. %, or, more specifically, about 5 wt. % to about 20 wt. %,” is inclusive of the endpoints and all intermediate values of the ranges of “about 5 wt. % to about 25 wt. %,” etc.). The modifier “about” used in connection with a quantity is inclusive of the stated value and has the meaning dictated by the context (e.g., includes the degree of error associated with measurement of the particular quantity).

The subject matter disclosed herein relates generally to methods for improving inversion layer mobility and providing low defect density in a semiconductor device based upon a silicon carbide (SiC) substrate. Conventional SiC based devices often exhibit poor inversion layer mobility, i.e., poor mobility of electrons from a source region to a drain region. This poor inversion layer mobility is thought to result from traps, also referred to as defects, present at the SiC/SiO interface. These traps, in turn, are thought to possibly result from the presence of atomistic structural defects at or within one or several atomic layers at the SiC-silicon dioxide interface. While the precise nature of one or more such defect types is under intense investigation, it is believed that they are related to the presence of carbon, since the above stated phenomenon are restricted to SiC devices and not in the equivalent silicon devices.

There are provided herein silicon carbide substrates, semiconductor devices based upon the substrates and methods of forming these that have/result in a lower concentration of defects at this interface. More particularly, the methods provide for the incorporation of an additive into the atomic structure of the gate oxide that can provide for a reduction in the excess carbon at the interface, and thus the concentration of defects. While not wishing to be bound by any theory, it is thought that effective additives for this purpose do so by i) providing alternate reaction paths that do not form the defects, ii) providing reaction paths that enhance the degeneration of existing defects, or iii) providing reaction paths that render any defects electrically benign, during the growth of the gate oxide layer.

Additives capable of reducing defects in one or more of these ways, or via the catalysis of any reaction having the same effect, may be used in the present methods. It is thought that any additive capable of acting as a glass modifier, i.e., capable of dissolving in glass, will also be capable of reducing defects via the provision of one or more of the aforementioned reaction paths, or via the catalysis of one or more of the aforementioned reaction paths. Such additives are expected to include, but not be limited to, lithium, rubidium, cesium, cerium, fluorine and sulfur, as well as other alkali elements.

One desirable attribute of the additive(s) is that it is readily incorporated into the atomic structure of silica glass, disrupting at least a portion of the existing atomic bonds, so that alternate reaction paths and/or alternate reaction products are possible. Additives with such attributes are considered to be within the category of glass formers and glass modifiers. Desirably, when such additives are added to silica glass, the glassy structure will be maintained.

Of these, those that are incorporated into the atomic structure at the interface in such a way that they are immobile can be preferred since they are not expected to interfere with the functioning of the overall device, whereas those that are more mobile may destabilize the device. One example of such an additive is cesium. However, if additives that are more mobile are preferred for other reasons, e.g., availability, cost, etc., the additives may be removed after formation of the gate oxide layer if it is suspected that their presence may detrimentally impact the stability of a device based upon the substrate. Additives that may beneficially be removed in a post-oxidation process include lithium, rubidium, fluoride, sulfur, and the alkali elements. Any combination of the additives, whether considered mobile or immobile, may also be utilized.

The desired additive will desirably be incorporated into the oxide at a concentration that will be capable of at least minimally reducing the defects present at the interface, and preferably will be incorporated in an amount that will provide a device based upon the oxidized substrate with an inversion mobility of at least about 60 cm²/Vs. Concentrations thought to be capable of doing this approximate the typical defect concentration range, i.e., from about 10¹⁰ per cm² to about 10¹⁴ per cm², and useful concentrations are thus within this range, and inclusive of all subranges therebetween.

The desired additive(s) may be incorporated into the oxide via any known method capable of providing the desired concentration of the additive within the oxide layer. For example, the oxidized SiC substrate may be placed in a vessel at high temperature wherein the additive is present as a vapor and impinges on the substrate. Alternatively, the oxidized substrate may be placed in a high vacuum chamber and a thermal evaporation source comprising the additive material activated. One other example of a suitable method of incorporating the desired additive into the oxidized SiC substrate involves placing the device in contact with a liquid comprising the desired additive. The desired additive may also be deposited on the SiC substrate via ion implantation.

In one particular embodiment of the invention, the SiC substrate may be placed in an oxidation chamber, and before, during or after oxidation, desirably before oxidation, the additive introduced into the chamber so that it becomes incorporated into the atomic structure of the oxide layer as the oxide layer is grown upon the substrate comprising the additive. It is to be understood that the SiC substrate may comprise some form of oxide on the surface thereof, e.g., native oxide, so that in embodiments wherein the additive is said to be introduced before or prior oxidation, the presence of such an amount of oxide is not precluded. The oxidized SiC substrate, when used as the basis of a semiconductor device, is expected to provide the device with an inversion layer mobility of at least about 60 cm²/Vs.

Optionally, prior to the formation or provision of any other features, the oxidized SiC substrate incorporating the additive may be subjected to a post oxidation step for removing any remaining additive, as may desirably be done in those embodiments of the invention wherein the additive is mobile and thus capable of rendering a device based upon the SiC substrate unstable. Any process capable of doing so may be utilized for this purpose, and examples of these include, but are not limited to electric field induced drift.

Those of ordinary skill in the art are familiar with electric field induced drift and capable of performing it on the SiC substrate. For purposes of completeness, and generally speaking, electric field induced drift involves covering the oxide layer and backside of the SiC substrate with metal, e.g., aluminum. The substrate is then heated, while an electric field of 1-2 MV/cm is applied between the pads. The substrate is then cooled to room temperature under bias. This treatment results in virtually all of the additive present in the oxide migrating to the aluminum oxide interface. The aluminum layers would then be removed, and if desired, a thin layer of the oxide (e.g., 5 nm), in buffered acid.

The oxidized SiC substrate incorporating the additive, or having had the additive removed, as the case may be, may also optionally be annealed by any known method of doing so known to those of ordinary skill in the art. Generally speaking, the oxidized SiC substrate may be annealed, if the same is desired, by cooling the oxidized SiC substrate to a temperature of about 1400° C., or 1200° C. or even as low as 1000° C. and holding the oxidized SiC substrate at this temperature for as long as desired. Annealing may also assist in relieving any strain in the oxidized SiC substrate, and if the same is desired, time periods of at least 10 minutes and up to about 10 hours, inclusive of all subranges therebetween, are generally sufficient to provide the desired strain relief.

Any optional, yet desired, anneal step may also be modified to provide for the elimination of any additive remaining after oxidation, if desired. More specifically, if the substrate is desirably annealed, and such an anneal step would also desirably reduce the concentration of, or eliminate, any additive present in the oxide layer, a first anneal may be performed in an inert gas, or halogen cleaning gas. Suitable gases for this purpose include chlorine, fluorine, chloro-hydrocarbons, freons, and other halogen containing gases. If desired, a second anneal step may be conducted, and if conducted would be expected to passivate any remaining defects at the SiC/oxide interface.

The SiC substrate may be processed to provide any desired semiconductor device. For example, to provide an N-type MOSFET, source, drain, and p-well regions may be doped by ion implantation, diffusion or epitaxy. Next, the doped regions may optionally be activated by annealing at high temperature. Then, the sample is oxidized as described above. A polysilicon layer may be deposited, and subsequently patterned and/or etched to provide a polysilicon gate electrode, which may preferably be doped, for example p+ doped. Ohmic contacts can then be formed over the source and drain regions and the upper portion of the polysilicon gate electrode, and are then annealed to provide the completed N-type MOSFET.

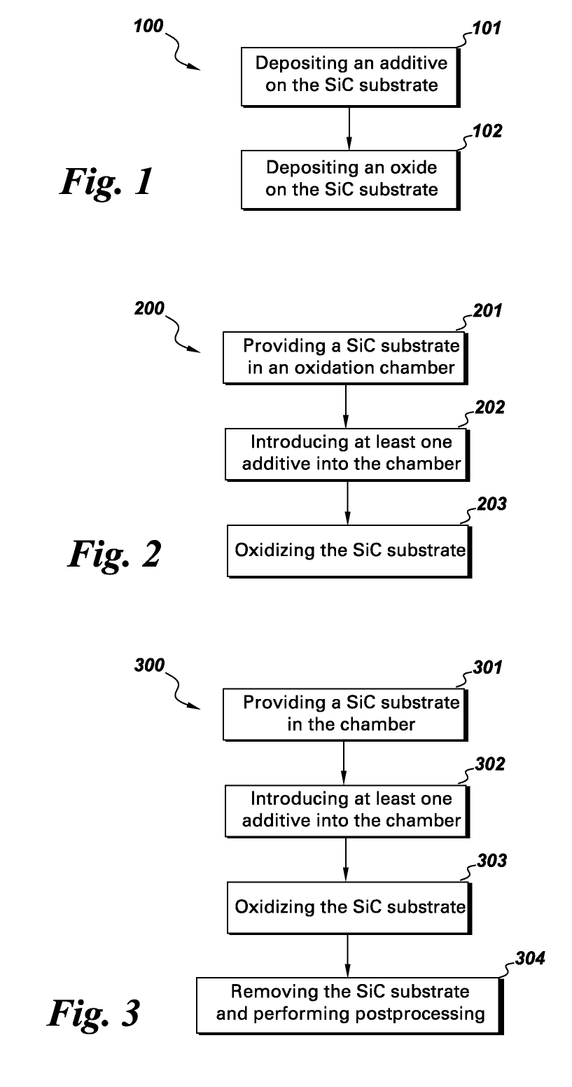

In FIG. 1, a flow chart schematically illustrating the present method 100, shows the deposition of an additive on the SiC-substrate in a first step 101. The SiC substrate may comprise an amount of oxide, either deposited or native, or may be substantially devoid of oxide at step 101. The desired additive may be deposited according to any known method, e.g., as by vapor impingement, exposure of the substrate to a thermal evaporation source of the additive, contact of the substrate with a liquid comprising the additive, ion implantation, etc. Whatever method chosen, the additive will be deposited relative to the SiC surface in an amount effective, once incorporated into the oxide layer deposited in step 102, to provide any of the reaction paths discussed hereinabove. Concentrations of from about 10¹⁰ per cm² to about 10¹⁴ per cm², inclusive of all subranges therebetween, are expected to be suitable.

An oxide is subsequently deposited on the SiC method at step 102, according to any known method. Desirably, the additive deposited in step 101 will become incorporated into the atomic structure of the SiO, disrupting at least a portion of the atomic bonds therein, but the glassy structure of the oxide layer maintained. A completed semiconductor device based upon a substrate so treated is expected to exhibit an inversion layer mobility of up to about 60 cm²/Vs.

FIG. 2 is a flowchart illustration of an additional embodiment 200 of the present method, wherein in first step 201, a SiC-substrate is provided in an oxidation chamber. The oxidation chamber may be heated or at an elevated pressure as may be dictated by the desired additive and its desired method of deposition. At step 202, the desired additive is introduced into the chamber in a suitable physical form, e.g., solid, liquid or vapor.

Oxidation of the SiC-substrate is then conducted at step 203, with an oxidation agent introduced into the chamber at a concentration and for an amount of time to provide an oxide layer of the desired thickness, typically from about 20 nm to about 200 nm. Either wet or dry oxidation may be used at step 203.

FIG. 3 is a schematic illustration of yet another embodiment 300, wherein at a first step 301, a SiC substrate is provided in an oxidation chamber. At step 302, at least one additive is introduced into the chamber. Any glass modifier may be used, e.g., lithium, rubidium, cesium, cerium, fluorine and sulfur, as well as other alkali elements, as well as combinations of two more of these. At step 303, oxidation of the SiC substrate is carried out according to any desired oxidation protocol, using any desired oxidation agent. The SiC substrate is removed and subject to post-processing at step 304. Step 304 may, for example, involve processing steps to substantially remove any additive remaining in the oxide layer, as may be desired in those embodiments wherein the presence of the additive in the completed device may result in instability of the same.

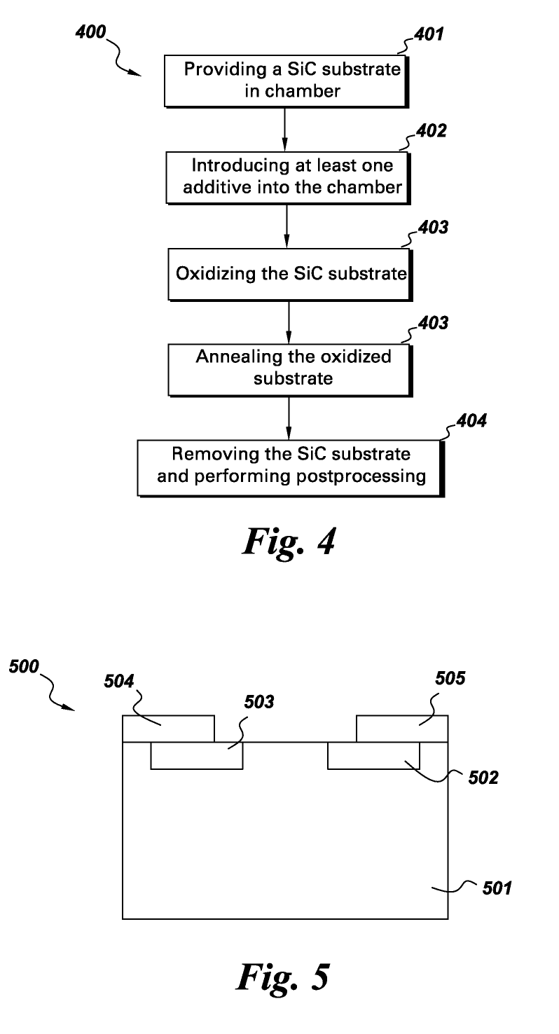

A further embodiment of the present method is schematically illustrated in FIG. 4, wherein at step 401, a SiC substrate is provided in an oxidation chamber. The chamber may be at ambient temperature, may be preheated, may be heated once the SiC substrate is placed therein, or may be heated prior to oxidation step 403. Desirably, during introduction of the additive and/or oxidation, the chamber will be at a temperature of at least about 700° C. to about 1800° C. or any temperature, or range of temperatures, therebetween. That is, the temperature may fluctuate during oxidation either due to normal operating variances, or can be made to vary within this range if desired. At step 402, at least one additive is introduced into the chamber and at least some amount thereof deposited relative to the SiC substrate.

The SiC substrate is oxidized at step 403. Once oxidation step 403 has provided substrate SiC with an oxide layer of the desired thickness, the substrate may be annealed at step 404 in an environment suitable for the same. At step 405, the substrate is further processed to provide a complete semiconductor device, e.g., the oxidized SiC substrate may have gate, source and drain contacts provided thereon, and optionally a passivation layer, to provide a SiC MOSFET.

Turning now to FIG. 5, there is shown an in-process semiconductor device. Semiconductor device 500 may generally comprise a SiC p-type doped substrate 501, source contact 504, drain contact 505, N+ doped source region 503, and N-doped drain region 502. As shown, source contact 504 and drain contact 505 are in electrical contact with source region 503 and drain region 502, respectively. Regions 503 and 502, and contacts 504 and 505 are not critical and may comprise any known material and be formed by any known method. Additionally, contacts 504 and 505 may be formed on device 500 post-oxidation, if desired. For example, contacts 504 and 505 could be deposited metal, e.g., aluminum.

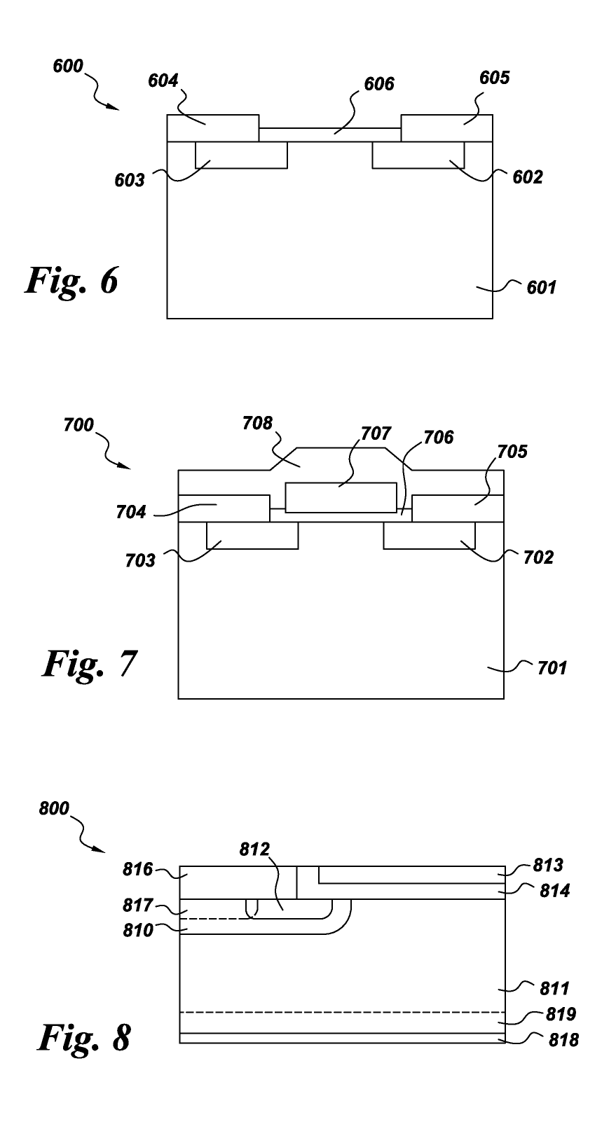

Referring now to FIG. 6, oxide layer 606 is provided by oxidizing semiconductor device 600. Prior to, during or after the provision of oxide layer 606, an additive may be deposited relative to device 600 so that that the additive will become incorporated into the atomic structure of the SiO, disrupting at least a portion of the atomic bonds therein, while also substantially maintaining the glassy structure of the oxide layer. A completed semiconductor device based upon a substrate so treated is expected to exhibit an inversion layer mobility of at least about 60 cm²/Vs.

FIG. 7 shows a completed semiconductor device 700, more specifically a SiC MOSFET. More particularly, once an additive has been incorporated into the atomic structure of the oxide layer so that reaction paths are provided within the oxide layer as it forms that i) do not result in the formation of substantial amounts of defects, ii) enhance the degeneration of existing defects, and/or iii) render any defects electrically benign,

Device 700 is desirably further processed. Such processing may provide additional features, such as gate contact 707, and if desired, passivation layer 708. By application of the present method, device 700 is expected to exhibit inversion layer mobilities, i.e., mobility of electrons from source region 703 to drain region 702, of at least about 60 cm²/Vs.

An alternative embodiment of the present device is shown in FIG. 8. More particularly, FIG. 8 shows a partial cross sectional view of an N-type, SiC vertical MOSFET cell 800. In an actual power MOSFET device, several of such cells 800 would be connected in parallel.

As is shown in FIG. 8, the vertical MOSFET cell 800 includes a P-well region 810 formed within a top surface of an N− drift layer 811, and an N+ source region 812 formed within the P-well region 810. Gate insulating film 814 is provided by oxidizing semiconductor device 800.

Prior to, during or after oxidation to provide gate insulating film 814, an additive is desirably deposited relative to cell 800 so that at least some amount of the additive is incorporated into the atomic structure of gate insulating film 814. Desirably, the amount of additive incorporated into gate insulating film 814 will be sufficient to provide reaction paths within gate insulating film 814 as it forms that i) do not result in the formation of substantial amounts of defects, ii) enhance the degeneration of existing defects, and/or iii) render any defects electrically benign. The additive may so provide by functioning as a catalyst for such reactions, and if this is the case, no, or substantially no, additive may be detectable in finished MOSFET cell 800.

Thereafter, gate electrode 813 is formed on a gate insulating film 814, and over a portion of the P-well region 810 interposed between the N+ source region 812 and an exposed surface portion of the N− drift layer 811. In addition, a source electrode 816 is formed in contact with the surface of both the N+ source region 812 and the P-well region 810. As shown, a more highly doped P+ region 817, located at the top of the P-well region 810, enhances ohmic contact between the source electrode 816 and the P-well region 810. MOSFET 800 further includes a drain electrode 818 formed in contact with the rear surface of an N+ drain region 819.

In operation of the vertical MOSFET 800, a positive voltage applied to the gate electrode 813 induces an inversion layer in the surface of the P-well 810 directly beneath the gate insulating film 814, such that current flows between the source electrode 816 and drain electrode 818 (and through the N− drift layer 811). If the positive voltage to the gate electrode 813 is removed, the inversion layer beneath the gate insulating film 814 in the P-well 810 disappears and a depletion layer spreads out, thereby blocking current flow through the P-well 810.

As indicated above, the P-well region 810 is typically formed through implantation of the N− drift layer 811 by a suitable P-type dopant (e.g., boron, aluminum). Subsequently, the N+ source region 812 and the more highly doped P+ region 817 are also formed within the P-well region 810 through similar dopant implantation steps. By application of the present method, device 800 is expected to exhibit inversion layer mobilities, i.e., mobility of electrons from source region 812 to drain region 819, of at least about 60 cm/Vs.

### EXAMPLE 1

### Incorporation of an Additive into the Atomic Structure of an Oxide Layer

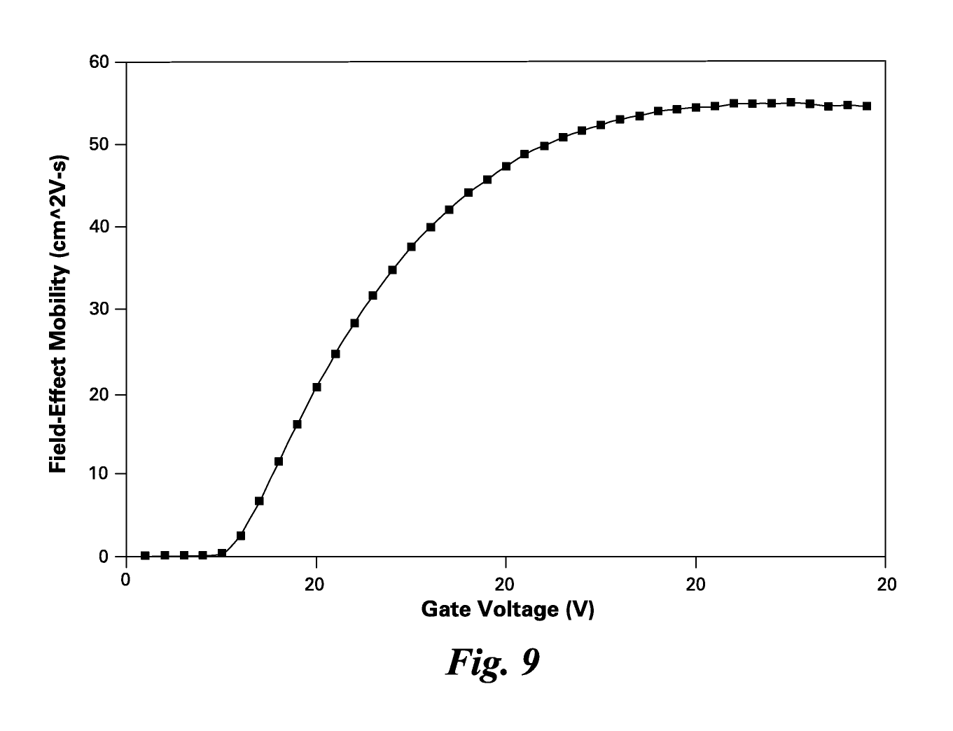

Silicon dioxide was grown on silicon carbide substrates with dry oxygen at 1150° C. for 4 hours, resulting in an average thickness of grown silicon dioxide of 380 Å. Next, the samples were impregnated with cesium by boiling the SiC substrates in 1×10⁻¹ molar concentration of cesium chloride (CsCl) for 15 minutes. Then, silicon dioxide was grown at 900° C. for 20 minutes in dry oxygen in the presence of cesium. The average thickness of the silicon dioxide grown in the presence of cesium was 180 Å, making the total gate oxide thickness about 560 Å. FIG. 9 shows the field-effect mobilities with increasing gate voltages of these samples. As shown, field-effect mobilities of from about 40 cm²/V-s to about 55 cm²/V-s are seen at gate voltages of between about 10 V and about 20 V.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A silicon carbide substrate comprising a gate oxide layer for use in the manufacture of a semiconductor device having at least one additive incorporated into the atomic structure of the oxide layer.

2. The silicon carbide substrate of claim 1, wherein the additive comprises one or more glass modifiers.

3. The silicon carbide substrate of claim 2, wherein the additive comprises lithium, rubidium, cesium, cerium, fluorine, sulfur, other alkali elements or combinations of these.

4. The silicon carbide substrate of claim 3, wherein the additive comprises lithium, cesium, or combinations thereof.

5. A semiconductor device based upon a silicon carbide substrate comprising a gate oxide layer having at least one additive incorporated into the atomic structure thereof.

6. The semiconductor device of claim 5, wherein the additive comprises one or more glass modifiers.

7. The semiconductor device of claim 6, wherein the additive comprises lithium, rubidium, cesium or combinations of these.

8. The semiconductor device of claim 7, wherein the additive comprises cesium.

9. The semiconductor device of claim 5, wherein the device comprises an inversion layer mobility of at least about 60 cm²/Vs.

10. The semiconductor device of claim 5, wherein the device comprises an SiC based MOSFET.

11. A method for the manufacture of a semiconductor device based upon a silicon carbide substrate and comprising an oxide layer, comprising incorporating at least one additive into the atomic structure of the oxide layer so that at least some portion of the additive is available to reactions occurring at the interface of the silicon carbide substrate and the oxide layer.

12. The method of claim 11, wherein the additive comprises one or more glass modifiers.

13. The method of claim 12, wherein the additive comprises lithium, rubidium, cesium, cerium, fluorine, sulfur, other alkali elements or combinations of these.

14. The method of claim 13, wherein the additive comprises rubidium, cesium, or combinations of these.

15. The method of claim 11, wherein the additive is incorporated into the atomic structure of the oxide layer by impinging a vapor comprising the additive onto the device surface prior to growth of the oxide layer.

16. The method of claim 11, wherein the additive is incorporated into the atomic structure of the oxide layer by activating a thermal evaporation source of the additive within a high vacuum chamber within which the device is disposed prior to the growth of the oxide layer.

17. The method of claim 11, wherein the additive is incorporated into the atomic structure of the oxide layer by contacting the device with a liquid comprising the additive prior to growth of an oxide layer.

18. The method of claim 11, wherein the additive is incorporated into the atomic structure of the oxide layer by ion implantation.

19. The method of claim 11, further comprising removing any residual additive after growth of the oxide layer.
